(19) United States
(12) Patent Application Publication
(10) Pub. No.: US 2025/0275383 A1
(43) Pub. Date: Aug. 28, 2025

(54) OXIDE SEMICONDUCTOR THIN-FILM TRANSISTOR ARRAY SUBSTRATE AND STRETCHABLE DISPLAY DEVICE INCLUDING SAME

(71) Applicant: LG Display Co., Ltd., Seoul (KR)

(72) Inventors: Jaeman Jang, Paju-si (KR); Uyhyun Choi, Paju-si (KR)

(73) Assignee: LG Display Co., Ltd., Seoul (KR)

(21) Appl. No.: 19/006,692

(22) Filed: Dec. 31, 2024

(30) Foreign Application Priority Data
Feb. 22, 2024 (KR) 10-2024-0025980

(51) Int. Cl. H10K 59/124; H10D 30/67; H10D 86/40; H10D 86/60; H10H 29/41; H10H 29/49; H10K 59/131; H10K 77/10; H10K 102/00

(52) U.S. Cl. CPC H10K 59/124; H10D 30/6755; H10D 86/423; H10D 86/481; H10D 86/60; H10H 29/41; H10H 29/49; H10K 59/131; H10K 77/111; H10K 2102/311

(57) ABSTRACT

An oxide semiconductor thin-film transistor array substrate and a stretchable display device including the same are provided. The stretchable display device can include a substrate having a pixel area and a stretchable area, an insulating member disposed over the substrate in the pixel area and including a first open area exposing the stretchable area, and a thin-film transistor disposed over an area including a side surface of the insulating member exposed by the first open area. Accordingly, the area occupied by the thin-film transistor can be reduced, thereby the size of the pixel area can be reduced and resolution can be improved.

### CROSS REFERENCE TO RELATED APPLICATION

This application claims priority to Korean Patent Application No. 10-2024-0025980, filed in the Republic of Korea on Feb. 22, 2024, the entirety of which is hereby expressly incorporated by reference into the present application.

### BACKGROUND

### Technical Field

Embodiments of the present disclosure relate to an oxide semiconductor thin-film transistor (TFT) array substrate and a stretchable display device including the same.

### Description of the Related Art

With the development of the information society, demand for image display devices is increasing. As such, a range of display devices, such as liquid crystal display (LCD) devices and organic light-emitting diode display devices, have come into use.

Display devices can be implemented in a variety of forms, depending on the function to be provided to users. For example, display devices can be implemented in a non-fixed form, such as a foldable display device or a rollable display device. In addition, display devices can be implemented in a stretchable form that can change the shape or size depending on the condition in which display devices are placed or an external force applied to display devices. Since stretchable display devices are stretchable, implementation of display devices having various shapes can further be facilitated.

### BRIEF SUMMARY OF THE DISCLOSURE

Various aspects of the present disclosure provide an oxide semiconductor thin-film transistor (TFT) array substrate able to improve resolution and a stretchable display device including the same.

Also aspects of the present disclosure provide an oxide semiconductor TFT array substrate able to improve stretching characteristics and a stretchable display device including the same.

Also aspects of the present disclosure provide an oxide semiconductor TFT array substrate able to reduce device characteristics deterioration due to stretching stress, and a stretchable display device including the same.

The objectives of the present disclosure are not limited to the aforementioned description, and other objectives not explicitly disclosed herein will be clearly understood by those having ordinary knowledge in the technical field to which the present disclosure pertains from the description provided hereinafter.

A stretchable display device according to embodiments of the present disclosure includes a substrate including a pixel area and a stretchable area; an insulating member disposed over the substrate in the pixel area and including a first open area exposing the stretchable area; and a thin film transistor (TFT) disposed over an area including a side surface of the insulating member exposed by the first open area.

A stretchable display device according to embodiments of the present disclosure includes a substrate including a pixel area, a stretchable area, and a pad area; a buffer layer disposed over the substrate; a first active pattern disposed over the pixel area of the buffer layer, a first gate insulating layer disposed over the buffer layer and covering the first active pattern; a first gate electrode disposed over the first gate insulating layer to overlap a portion of the first active pattern; an interlayer insulating layer disposed over the first gate insulating layer and covering the first gate electrode; a first open area penetrating the interlayer insulating layer, the first gate insulating layer, and the buffer layer to expose the stretchable area of the substrate; a first electrode disposed over the pixel area of the substrate, with at least a portion thereof being exposed by the first open area; a second electrode disposed over the interlayer insulating layer above the first electrode to be adjacent to the first open area; a second active pattern disposed over the second electrode and extending to the first electrode along a side surface of the interlayer insulating layer, a side surface of the first gate insulating layer, and a side surface of the buffer layer exposed by the first open area; a second gate insulating layer disposed over the interlayer insulating layer, covering the second active pattern, and including a second open area exposing the stretchable area of the substrate; and a second gate electrode disposed over the second gate insulating layer to overlap the second active pattern.

A TFT array substrate according to embodiments of the present disclosure includes a buffer layer disposed over a substrate; a first gate insulating layer disposed over the buffer layer, an interlayer insulating layer disposed over the first gate insulating layer; a first open area penetrating the interlayer insulating layer, the first gate insulating layer, and the buffer layer to expose a portion of the substrate; a first TFT; and a second TFT. The first TFT can include a first oxide semiconductor pattern disposed over the buffer layer and covered with the first gate insulating layer; the first gate insulating layer, and a first gate electrode disposed over the first gate insulating layer to overlap a portion of the first oxide semiconductor pattern. The second TFT can include a first electrode disposed over the substrate, with at least a portion thereof being exposed by the first open area; a second electrode disposed over the interlayer insulating layer above the first electrode to be adjacent to the first open area; a second oxide semiconductor pattern disposed over the second electrode, and extending to the first electrode along a side surface of the interlayer insulating layer, a side surface of the first gate insulating layer, and a side surface of the buffer layer exposed by the first open area; a second gate insulating layer disposed over the interlayer insulating layer and covering the second oxide semiconductor pattern; and a second gate electrode disposed over the second gate insulating layer to overlap the second oxide semiconductor pattern.

According to embodiments of the present disclosure, in the oxide semiconductor TFT array substrate and the stretchable display device including the same, a TFT can be disposed on a side surface of the insulating member exposed by the first open area exposing the stretchable region to reduce the area occupied by the TFT, thereby reducing the size of the pixel area and improving resolution.

According to embodiments of the present disclosure, in the oxide semiconductor TFT array substrate and the stretchable display device including the same, the size of the pixel area can be reduced by reducing the area occupied by the TFT, and the free area resulting from the reduced pixel area can be used as a stretchable area to improve stretching characteristics.

According to embodiments of the present disclosure, in the oxide semiconductor TFT array substrate and the stretchable display device including the same, the impact of stretching stress on the TFT can be reduced to reduce damage to the TFT and reduce or prevent characteristics deterioration of the TFT.

According to embodiments of the present disclosure, in the oxide semiconductor TFT array substrate and the stretchable display device including the same, the oxide semiconductor can be conductorized by diffusing ions contained in the insulating member to form a conductorization region, thereby reducing the number of process steps. Accordingly, the effect of process optimization can be obtained.

The effects of the present disclosure are not limited to the aforementioned description, and other effects not explicitly disclosed herein will be clearly understood by those having ordinary knowledge in the technical field, to which the present disclosure pertains, from the description provided hereinafter.

### BRIEF DESCRIPTION OF THE DRAWINGS

The above and other objectives, features, and advantages of the present disclosure will be more clearly understood from the following detailed description, taken in conjunction with the accompanying drawings, in which:

FIG. 1 illustrates a schematic system configuration of a stretchable display device according to embodiments of the present disclosure;

FIG. 2 is a perspective view schematically illustrating an active area of a stretchable display device according to embodiments of the present disclosure;

FIGS. 3 and 4 are cross-sectional views each illustrating a TFT of an oxide semiconductor TFT array substrate included in a stretchable display device according to embodiments of the present disclosure;

FIG. 5 is a cross-sectional view illustrating an oxide semiconductor TFT array substrate included in a stretchable display device according to embodiments of the present disclosure;

FIGS. 6 and 7 are cross-sectional views each illustrating a second TFT of an oxide semiconductor TFT array substrate included in a stretchable display device according to embodiments of the present disclosure; and

FIGS. 8A to 8F are cross-sectional views illustrating a method of manufacturing an oxide semiconductor TFT array substrate included in a stretchable display device according to embodiments of the present disclosure.

### DETAILED DESCRIPTION OF THE EMBODIMENTS

In the following description of examples or embodiments of the present disclosure, reference will be made to the accompanying drawings in which it is shown by way of illustration specific examples or embodiments that can be implemented, and in which the same reference numerals and signs can be used to designate the same or like components even when they are shown in different accompanying drawings from one another.

Further, in the following description of examples or embodiments of the present disclosure, detailed descriptions of well-known functions and components incorporated herein will be omitted when it is determined that the description can make the subject matter in some embodiments of the present disclosure rather unclear. The terms such as “including”, “having”, “containing”, “constituting” “made up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” can be used herein to describe elements of the present disclosure. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element can be included in at least one of two or more elements that “are connected or coupled to”, “contact or overlap”, etc. each other.

When time relative terms, such as “after”, “subsequent to”, “next”, “before”, and the like, are used to describe processes or operations of elements or configurations, or flows or steps in operating, processing, manufacturing methods, these terms can be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that can be caused by various factors (e.g., process factors, internal or external impact, noise, etc.) even when a relevant description is not specified. Further, the term “can” fully encompasses all the meanings of the term “may”.

Hereinafter, a variety of embodiments of the present disclosure will be described in detail with reference to the accompanying drawings. All the components of each display device according to all embodiments of the present disclosure are operatively coupled and configured.

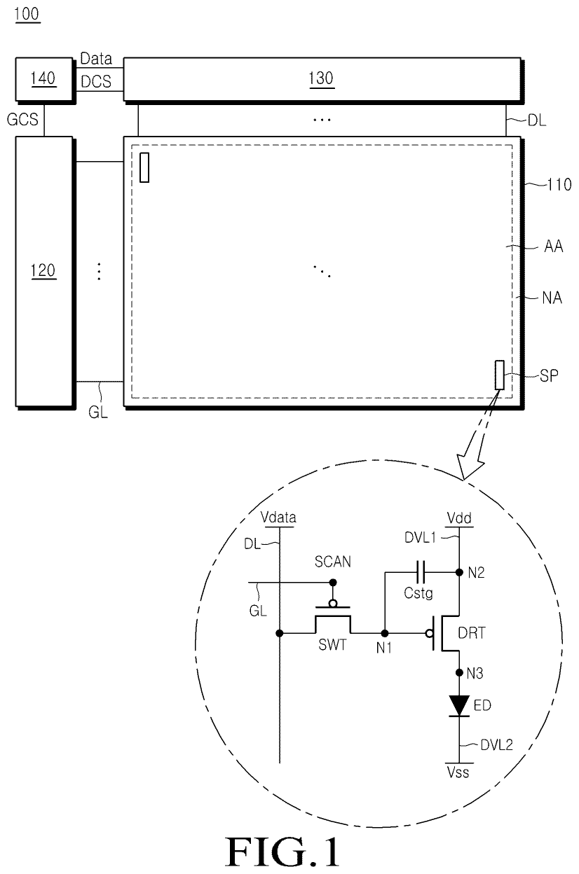

FIG. 1 illustrates a schematic system configuration of a stretchable display device according to embodiments of the present disclosure.

Referring to FIG. 1, a stretchable display device 100 can include a display panel 110 including an active area AA and a non-active area NA, as well as, a gate driver circuit 120, a data driver circuit 130, a controller 140, and the like for driving the display panel 110.

A plurality of gate lines GL and a plurality of data lines DL can be arranged on the display panel 110, and a plurality of subpixels SP can be disposed in areas where the gate lines GL intersect the data lines DL.

The gate driver circuit 120 is controlled by the controller 140, and sequentially outputs scanning signals to the gate lines GL arranged on the display panel 110 to control the driving timing of the subpixels SP.

The gate driver circuit 120 can include one or more gate driver integrated circuits (GDICs), which can be located on only a first side or on opposite sides of the display panel 110, depending on the driving system.

Each of the gate driver integrated circuits can be connected to a bonding pad on the display panel 110 by a tape-automated bonding (TAB) method or a chip-on-glass (COG) method, can be implemented by a gate-in-panel (GIP) method to be disposed directly on the display panel 110, or in some cases can be integrated on the display panel 110. In addition, each of the gate driver integrated circuits can be implemented by a chip-on-film (COF) method to be mounted on a film connected to the display panel 110.

The data driver circuit 130 receives image data from the controller 140, and converts the received image data into analog data voltages Vdata. Thereafter, the data driver circuit 130 outputs the data voltages Vdata to the data lines DL through the gate lines GL, respectively, according to the application timing of the scanning signal, so that each of the subpixels SP expresses a brightness corresponding to the image data.

The data driver circuit 130 can include one or more source driver integrated circuits (SDICs).

Each of the source driver integrated circuits can include a shift register, a latch circuit, a digital-to-analog converter (DAC), an output buffer, and the like.

Each of the source driver integrated circuits (SDICs) can be connected to a bonding pad on the display panel 110 by a TAB method or a COG method, can be disposed directly on the display panel 110, or in some cases can be integrated on the display panel 110. In addition, each of the source driver integrated circuits can be implemented by a COF method to be mounted on a film connected to the display panel 110, in which case each of the source driver integrated circuits can be mounted on a circuit film connected to the display panel 110, and be electrically connected to the display panel 110 through signal lines on the circuit film.

The controller 140 supplies various control signals to the gate driver circuit 120 and the data driver circuit 130, and controls the operation of the gate driver circuit 120 and the data driver circuit 130.

The controller 140 can be mounted on a printed circuit board, a flexible printed circuit, or the like, and electrically connected to the gate driver circuit 120 and the data driver circuit 130 through the printed circuit board, the flexible printed circuit, or the like.

The controller 140 controls the gate driver circuit 120 to output the scanning signal according to the timing realized for each frame, converts externally received image data into a data signal format readable by the data driver circuit 130, and outputs the converted image data to the data driver circuit 130.

The controller 140 receives various timing signals, including a vertical synchronization signal Vsync, a horizontal synchronization signal Hsync, an input data enable signal DE, a clock CLK, and the like, together with the image data from an external source (e.g., a host system).

The controller 140 generates various control signals using various timing signals received from the external source and delivers the control signals to the gate driver circuit 120 and the data driver circuit 130.

In an example, the controller 140 outputs various gate control signals GCS, including a gate start pulse GSP, a gate shift clock GSC, a gate output enable signal GOE, and the like, to control the gate driver circuit 120.

The gate start pulse GSP controls the timing at which the gate driver integrated circuits of the gate driver circuit 120 start operating. The gate shift clock GSC is a clock signal input to the gate driver integrated circuits in common to control the shift timing of the scanning signal. The gate output enable signal GOE specifies timing information of the gate driver integrated circuits.

The controller 140 also outputs various data control signals DCS, including a source start pulse SSP, a source sampling clock SSC, a source output enable signal SOE, and the like, to control the data driver circuit 130.

Here, the source start pulse SSP controls the timing at which the source driver integrated circuits of the data driver circuit 130 start data sampling. The source sampling clock SSC is a clock signal that controls the timing of the data sampling by each of the source driver integrated circuits. The source output enable signal SOE controls the output timing of the data driver circuit 130.

The stretchable display device 100 can further include a power management circuit that supplies various voltages or currents to, or controls various voltages or currents to be supplied to, the display panel 110, the gate driver circuit 120, the data driver circuit 130, and the like.

Each of the subpixels SP can be an area defined by the intersection of a gate line GL and a data line DL, and the stretchable display device 100 can be provided with emitting elements ED. In an example, when the stretchable display device 100 is an organic light-emitting display device, an organic light-emitting diode (OLED) and a plurality of circuit elements can be disposed in each of the subpixels SP. In addition, by controlling the current supplied to the OLEDs disposed in the subpixels SP, each of the subpixel SPs can express a brightness corresponding to the image data. In another example, in some cases, the emitting element ED disposed in each of the subpixels SP can be a light-emitting diode (LED) or a micro light-emitting diode (μLED).

In addition to the emitting element ED, circuit elements such as thin film transistors can be disposed in the subpixel SP.

In an example, as shown in FIG. 1, each of the subpixels SP can include two TFTs and one capacitor in addition to the emitting element ED.

A switching transistor SWT can be electrically connected to the data line DL and a first node N1. The switching transistor SWT can be controlled by a scanning signal supplied to the gate line GL, and can control the supply of a data voltage Vdata to the first node N1, which is the gate node of a driving transistor DRT.

The driving transistor DRT can be electrically connected to the first driving voltage line DVL1 through which the first driving voltage Vdd is supplied and the emitting element ED. Here, the first driving voltage Vdd can be a high-potential driving voltage.

The driving transistor DRT can be controlled by the data voltage Vdata supplied to the first node N1, and can control the current supplied to the emitting element ED.

Both the switching transistor SWT and the driving transistor DRT are shown implemented as P-type transistors for example, but can be implemented as N-type transistors in some cases.

The storage capacitor Cstg can be electrically connected to the first node N1 and a second node N2, and can maintain the data voltage Vdata for a single frame.

The emitting element ED can be electrically connected to the driving transistor DRT and the second drive voltage line DVL2 through which a second drive voltage Vss is supplied Here, the second driving voltage Vss can be a low-potential driving voltage.

The emitting element ED can emit light according to the current supplied through the driving transistor DRT. That is, the emitting element ED can express a brightness according to the current supplied through the driving transistor DRT according to the data voltage Vdata supplied to the first node N1, and can express a luminance according to the image data. In addition, the subpixel SP can further include a TFT or a capacitor depending on the type.

The stretchable display device 100 described above can display an image in a state in which stretchable display device 100 is stretched by an external force.

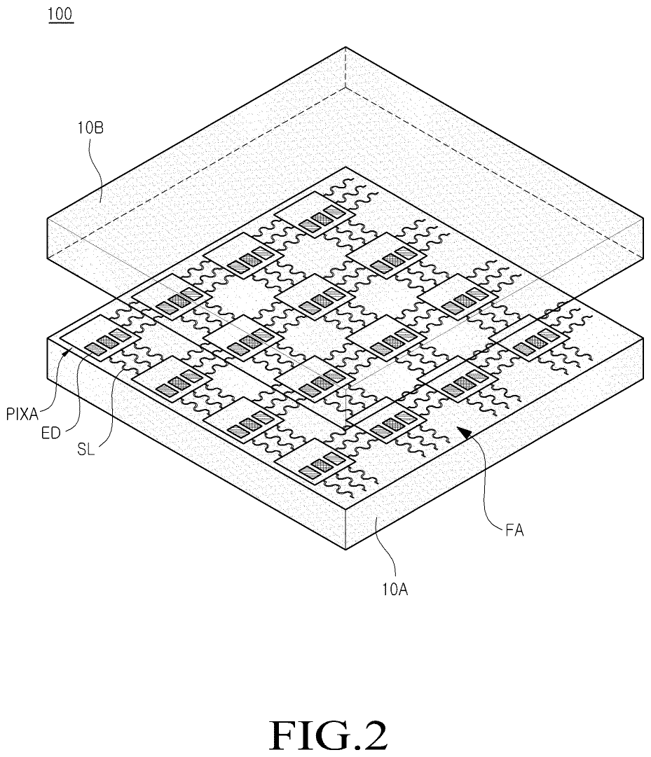

FIG. 2 is a perspective view schematically illustrating an active area of a stretchable display device according to embodiments of the present disclosure.

Referring to FIG. 2, the stretchable display device 100 can include a first substrate 10A and a second substrate 10B.

The first substrate 10A is a substrate for supporting and protecting the various components of the stretchable display device 100. The second substrate 10B is a substrate for covering and protecting the various components of the stretchable display device 100.

The first substrate 10A and the second substrate 10B can be formed of an insulating material that is bendable or stretchable. For example, the first substrate 10A and the second substrate 10B can include polyimide (PI), polyacrylate, polyacetate, silicone rubber such as polydimethylsiloxane (PDMS), or elastomer such as polyurethane (PU) or polytetrafluoroethylene (PTFE), and thus can have flexible properties. The material of the first substrate 10A and the material of the second substrate 10B can be the same, but can be varied without being limited thereto.

A plurality of pixel areas PIXA in each of which an emitting element ED and the like can be arranged in an active area of the first substrate 10A can be disposed to be spaced apart from each other. Pad areas can be provided in a non-active area of the first substrate 10A.

The pixel areas PIXA and the pad areas are areas having a fixed shape and can be regarded as rigid areas. The pixel areas PIXA and the pad areas can maintain a constant shape even in the case that the stretchable display device 100 is in a stretched state.

Areas other than the pixel areas PIXA and the pad areas are stretchable and can be considered as stretchable areas. A plurality of signal lines SL can be disposed in the stretchable areas.

The signal lines SL can be electrically connected to elements disposed in the pixel areas PIXA and/or pads disposed in the pad areas. The signal lines SL can be disposed, for example, in a bent form in the stretchable areas between the pixel areas PIXA. Thus, the length of a signal lines SL disposed between the pixel areas PIXA can be greater than a straight distance between adjacent pixel areas PIXA. In another example, the signal lines SL can be disposed in a bent form in the stretchable areas between the pixel areas PIXA and the pad areas. Thus, the length of the signal lines SL disposed between the pixel areas PIXA and the pad areas can be greater than the straight distance (e.g., direct distance) between a pixel area PIXA and an adjacent pad area.

When the stretchable display device 100 is in a stretched state, the distance between the pixel areas PIXA and/or the distance between the pixel areas PIXA and the pad areas can increase. That is, when an external force is applied to the stretchable display device 100, the pixel areas PIXA and the pad areas can maintain a fixed shape, and only the shape of the stretchable areas can change. This can also be regarded as the area change rate of the stretchable area is greater than the area change rate of the pixel areas PIXA and pad areas.

As the signal lines SL are disposed in a bent form, when the stretchable display device 100 is in a stretched state, the signal lines SL can be stretched to perform the signal supplying function. Accordingly, the stretchable display device 100 can perform display driving while maintaining constant performance in both the unstretched base state and the stretched state.

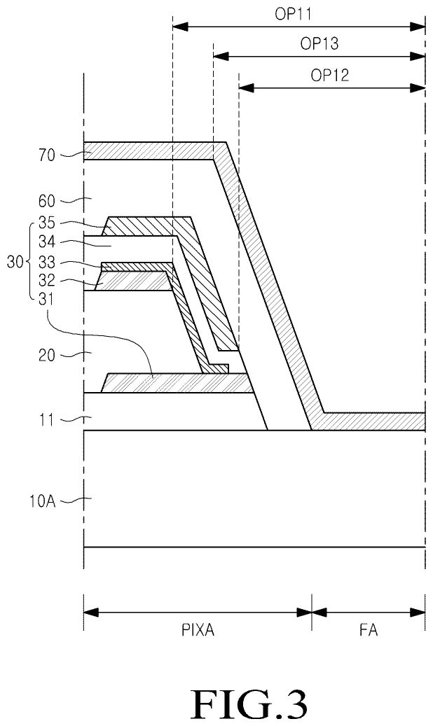

FIG. 3 is a cross-sectional view illustrating a TFT of an oxide semiconductor TFT array substrate included in a stretchable display device according to embodiments of the present disclosure.

Referring to FIG. 3, an insulating member 20 having a first open area OP11 exposing a stretchable area FA can be disposed over the first substrate 10A in the pixel area PIXA. A multi-buffer layer 11 can be disposed between the insulating member 20 and the first substrate 10A.

The multi-buffer layer 11 can have a structure, for example, in which a plurality of thin films are stacked together. For example, the multi-buffer layer 11 can have a structure in which silicon nitride (SiNx) and silicon oxide (SiOx) are alternately stacked. In another example, the multi-buffer layer 11 can have a structure in which organic and inorganic films are alternately stacked. The multi-buffer layer 11 can serve to retard upward diffusion of moisture and/or oxygen. In another example, the multi-buffer layer 11 can be omitted.

The insulating member 20 can include an inorganic material, and can have a single-layer structure or a multiple-layer structure. The insulating member 20 can be formed of, for example, silicon oxide (SiOx).

A thin-film transistor (TFT) 30 can be disposed on an area including a side surface of the insulating member 20 exposed by the first open area OP11. The TFT 30 can be one of the transistors included in a subpixel. For example, the TFT 30 can be one of the switching transistors and the driving transistors described with reference to FIG. 1.

The TFT 30 can include a first electrode 31, a second electrode 32, an active pattern 33, a gate insulating layer 34, and a gate electrode 35.

The first electrode 31 can be disposed over the multi-buffer layer 11 in the pixel area PIXA. At least a portion of the first electrode 31 can be exposed by the first open area OP11 of the insulating member 20. The remaining portions of the first electrode 31 can be covered with the insulating member 20.

The second electrode 32 can be disposed over the insulating member 20 above the first electrode 31 adjacent to the first open area OP11. One of the first electrode 31 and the second electrode 32 can be the source electrode of the TFT 30, and the other can be the drain electrode of the TFT 30.

The active pattern 33 can be disposed on the second electrode 32 and extend to the first electrode 31 along the side surface of the insulating member 20 exposed by the first open area OP11. The top portion of the active pattern 33 can be in contact with the second electrode 32 on the second electrode 32, and the bottom portion of the active pattern 33 can be over the first electrode 31 and in contact with the first electrode 31.

The active pattern 33 can be formed of an oxide semiconductor. The active pattern 33 can be an oxide semiconductor pattern.

The oxide semiconductor can include an oxide of a metal, such as zinc (Zn), indium (In), gallium (Ga), tin (Sn), or titanium (Ti), or a combination of such a metal and an oxide thereof. More specifically, oxide semiconductors can include zinc oxide (ZnO), zinc-tin oxide (ZTO), zinc-indium oxide (ZIO), indium oxide (InO), titanium oxide (TiO) indium-gallium-zinc oxide (IGZO), indium-zinc-tin oxide (IZTO), and the like. The active pattern 33 can have semiconductor properties.

The gate insulating layer 34 can be disposed on the top surface of the insulating member 20 and on the side surface of the insulating member 20 exposed by the first open area OP11, and can cover the active pattern 33. The gate insulating layer 34 can have a second open area OP12 exposing the stretchable area FA of the first substrate 10A.

The gate electrode 35 can be disposed over the gate insulating layer 34 to overlap the active pattern 33. A portion of the gate electrode 35 can overlap a portion of the active pattern 33 disposed over the side surface of the insulating member 20 and the top surface of the first electrode 31 exposed by the first open area OP11, and another portion of the gate electrode 35 can overlap another portion of the active pattern 33 disposed over the second electrode 32.

A passivation layer 60 can be disposed over the gate insulating layer 34 to cover the gate electrodes 35. The passivation layer 60 can have a third open area OP13 that exposes the stretchable area FA of the first substrate 10A. A side surface of the passivation layer 60 can be exposed by the third open area OP13.

The passivation layer 60 can be implemented as a single layer or a plurality of layers, and can be formed of an organic material. For example, the passivation layer 60 can include, but is not limited to, an acryl-based organic material.

A signal line 70 can be disposed over the passivation layer 60. The signal line 70 can extend to the stretchable area FA of the first substrate 10A along the side surface of the passivation layer 60 exposed by the third open area OP13. The signal line 70 can be electrically connected to at least one of the components disposed in the pixel area PIXA. The signal line 70 represents a component corresponding to the signal line SL described with reference to FIG. 2.

In this manner, by disposing the TFT 30 on the area including the side surface of the insulating member 20 exposed by the first open area OP11 that opens the stretchable area FA of the first substrate 10A, the area occupied by the TFT 30 can be reduced without reducing the effective channel length of the TFT 30. Accordingly, the resolution can be improved by reducing the size of the pixel area.

In addition, the free area resulting from the reduction in the size of the pixel area PIXA can be used as a stretchable area FA to increase the size of the stretchable area FA, thereby improving the stretching characteristics.

Furthermore, since the active pattern 33, the gate insulating layer 34, and the gate electrode 35 of the TFT 30 are arranged in a direction different from the direction in which the stretchable display device is stretched, the impact of the stretching stress on the TFT can be reduced, thereby reducing damage to the TFT 30 and reducing or preventing characteristic deterioration of the TFT.

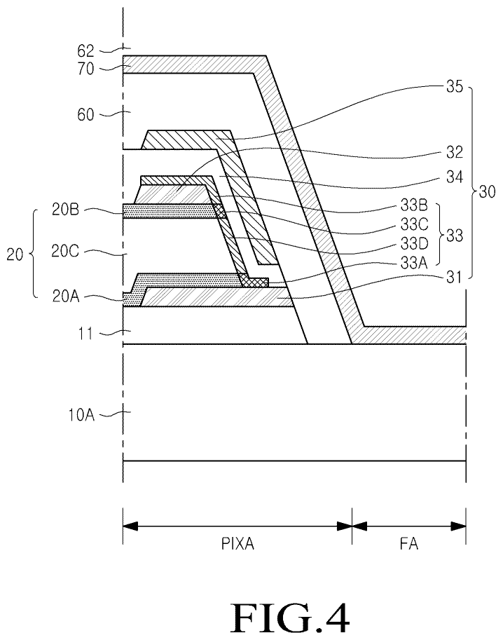

FIG. 4 is a cross-sectional view illustrating a TFT of an oxide semiconductor TFT array substrate included in a stretchable display device according to embodiments of the present disclosure.

Referring to FIG. 4, the active pattern 33 of the TFT 30 can be formed of an oxide semiconductor. The active pattern 33 can be an oxide semiconductor pattern. The active pattern 33 can include a first conductorization region 33A, a second conductorization region 33C, and a first oxide semiconductor region 33D.

The first conductorization region 33A can be disposed over the first electrode 31 and in direct contact with the first electrode 31.

The second conductorization region 33C can be disposed adjacent to the second electrode 32. The first oxide semiconductor region 33D can be disposed between the first conductorization region 33A and the second conductorization region 33C.

The first oxide semiconductor region 33D can have semiconductor properties. The first oxide semiconductor region 33D can be formed of an oxide semiconductor. The first conductorization region 33A and the second conductorization region 33C can be regions in which the oxide semiconductor is conductorized (i.e., becomes conductive) by hydrogen diffused from the insulating member 20.

The insulating member 20 can include a first insulating layer 20A disposed over the multi-buffer layer 11 and the first electrode 31, a second insulating layer 20C disposed over the first insulating layer 20A, and a third insulating layer 20B disposed over the second insulating layer 20C.

Each of the first insulating layer 20A, the second insulating layer 20C, and the third insulating layer 20B can be formed of an insulating material, but the first insulating layer 20A and the third insulating layer 20B can be formed of a material having a different hydrogen content than the second insulating layer 20C. The first insulating layer 20A and the third insulating layer 20B can be formed of a high hydrogen film material having a hydrogen content equal to or higher than a threshold value, and the second insulating layer 20C can be formed of a low hydrogen film material having a hydrogen content lower than the threshold value. Each of the first insulating layer 20A and the third insulating layer 20B can have a higher hydrogen content than the second insulating layer 20C.

In a subsequent process, the hydrogen contained in the first insulating layer 20A, the second insulating layer 20C, and the third insulating layer 20B can diffuse into the oxide semiconductor in the active pattern 33. A large amount of hydrogen from the first insulating layer 20A and the third insulating layer 20B having a high hydrogen content can diffuse into the oxide semiconductor, thereby conductorizing the oxide semiconductor. Even in the case that hydrogen diffuses from the second insulating layer 20C having a low hydrogen content into the oxide semiconductor, the oxide semiconductor can retain semiconductor properties instead of being conductorized. The threshold value refers to a minimum value or a value selected from a certain range of hydrogen content that enables the oxide semiconductor of the active pattern 33 to be conductorized.

For example, each of the first insulating layer 20A and the third insulating layer 20B can be formed of at least one selected from the group of materials including silicon nitride (SiNx), aluminum oxide (AlOx), hafnium oxide (HfOx), zirconium oxide (ZrOx), tantalum oxide (TaOx), or the like. The second insulating layer 20C can be formed of silicon oxide (SiOx).

Here, the silicon nitride (SiNx) can be formed using silane (SiH₄) and ammonia (NH₃) as source gases. Aluminum oxide (AlOx) can be formed using trimethyl aluminum (TMA, C₃H₉Al) as a source gas. Hafnium oxide (HfOx) can be formed using CpHf (C₁₁H₂₃N₃Hf) as a source gas. Zirconium oxide (ZrOx) can be formed using CpZr (C₁₁H₂₃N₃Zr) as a source gas. Tantalum oxide (TaOx) can be formed using CpTa (C₁₇H₃₉N₄Ta) as a source gas.

In response to the diffusion of hydrogen from the first insulating layer 20A, which is a high hydrogen film, the oxide semiconductor in a portion of the active pattern 33 in contact with the side surface of the first insulating layer 20A can be conductorized, thereby forming the first conductorization region 33A. The first conductorization region 33A is a region that is conductorized by the diffusion of hydrogen contained in the first insulating layer 20A into the oxide semiconductor, and can contact the side surface of the first insulating layer 20A.

In response to the diffusion of hydrogen from the third insulating layer 20B, which is a high hydrogen film, the oxide semiconductor in another portion of the active pattern 33 in contact with a side surface of the third insulating layer 20B can be conductorized, thereby forming the second conductorization region 33C. The second conductorization region 33C is a region that is conductorized by the diffusion of hydrogen contained in the third insulating layer 20B into the oxide semiconductor, and can contact the side surface of the third insulating layer 20B.

In another portion of the active pattern 33 in contact with the side surface of the second insulating layer 20C, which is a low hydrogen film, the oxide semiconductor is not conductorized. Accordingly, the first oxide semiconductor region 33D can be in contact with the side surface of the second insulating layer 20C.

As described above, the first conductorization region 33A and the second conductorization region 33C having a low resistance can be formed in the active pattern 33 of the TFT 30, thereby reducing the offset resistance and increasing the electrical conductivity. In addition, in the process used to fabricate the stretchable display device, the oxide semiconductor of the active pattern 33 can be conductorized by the diffusion of the hydrogen contained in the insulating member 20, thereby forming the TFT 30 having excellent electrical conductivity without adding any additional process steps.

The active pattern 33 can further include an extension region 33B. The extension region 33B can be disposed on the second electrode 32 and can be in direct contact with the second electrode 32. The extension region 33B can have different characteristics depending on the type of metallic material of the second electrode 32. The extension region 33B can be an oxide semiconductor region or a conductorization region in which an oxide semiconductor is conductorized.

In an example, the second electrode 32 can be formed of a metal having a higher oxidizing power than the oxide semiconductor. For example, the second electrode 32 can be formed of at least one of Ti, Al, MoTi, ITO, IZO, or Zr. In such a case, the metal of the second electrode 32 can be combined with the oxygen contained in the oxide semiconductor at the contact portion between the second electrode 32 and the oxide semiconductor, so that the oxide semiconductor can lose oxygen and be conductorized. In such a case, the extension region 33B can be a conductorization region.

In another example, the second electrode 32 can be formed of a metal having a lower oxidizing power than the oxide semiconductor. For example, the second electrode 32 can be formed of at least one of Mo, Cu, W, or Fe. In such a case, the metal of the second electrode 32 may not be combined with the oxygen contained in the oxide semiconductor at the contact portion between the second electrode 32 and the oxide semiconductor, so that the oxide semiconductor can remain in the oxide semiconductor state without being conductorized. In such a case, the extension region 33B can be an oxide semiconductor region.

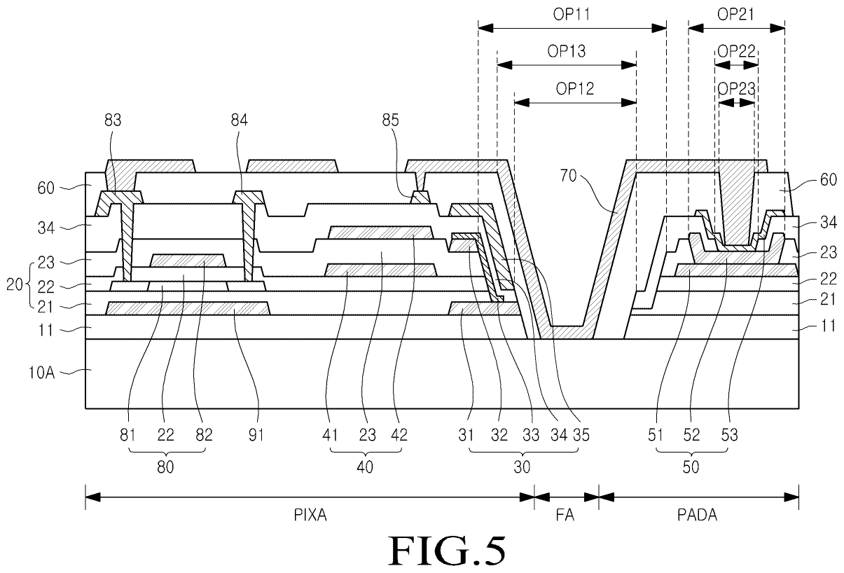

FIG. 5 is a cross-sectional view illustrating an oxide semiconductor TFT array substrate included in a stretchable display device according to embodiments of the present disclosure.

Referring to FIG. 5, a multi-buffer layer 11 covering the pixel area PIXA and the pad area PADA and exposing the stretchable area FA can be disposed over the first substrate 10A.

The multi-buffer layer 11 can have a structure in which, for example, a plurality of thin films are stacked together. For example, the multi-buffer layer 11 can have a structure in which silicon nitride (SiNx) and silicon oxide (SiOx) are alternately stacked. In another example, the multi-buffer layer 11 can have a structure in which organic films and inorganic films are alternately stacked. The multi-buffer layer 11 can serve to retard upward diffusion of moisture and/or oxygen. In another example, the multi-buffer layer 11 can be omitted.

The first electrode 31 of the second TFT 30 can be disposed over the multi-buffer layer 11 in the pixel area PIXA. The first electrode 31 can be one of the source electrode and the drain electrode of the second TFT 30.

In addition, or optionally, a bottom shield metal pattern 91 can be disposed over the multi-buffer layer 11 in the pixel area PIXA. The bottom shield metal pattern 91 can be disposed to overlap a first active pattern 81 of the first TFT 80. The bottom shield metal pattern 91 can serve to protect the first active pattern 81 of the first TFT 80. The bottom shield metal pattern 91 can prevent the generation of potential on the surface of the first substrate 10A and light from entering from the outside.

The first electrode 31 can be formed of the same material as the bottom shield metal pattern 91. The first electrode 31 and the bottom shield metal pattern 91 can include, but are not limited to, molybdenum (Mo).

The insulating member 20 can be disposed over the multi-buffer layer 11. The insulation member 20 can include an active buffer layer 21, a first gate insulating layer 22, and an interlayer insulating layer 23.

The active buffer layer 21 can be disposed over the multi-buffer layer 11 to cover the first electrode 31 and the bottom shield metal pattern 91. In an embodiment, the active buffer layer 21 can be formed of a low hydrogen film having a hydrogen content lower than a threshold value. For example, the active buffer layer 21 can be formed of silicon oxide (SiOx).

A first active pattern 81 of the first TFT 80 can be disposed over the active buffer layer 21 in the pixel area PIXA. The first active pattern 81 can include a channel region, and a source region and a drain region on opposite sides of the channel region. The first TFT 80 can be an oxide TFT. In such a case, the first active pattern 81 can be formed of an oxide semiconductor. In another example, the first active pattern 81 can be formed of an amorphous silicon (a-Si), polycrystalline silicon (poly-Si), organic semiconductor, or the like.

A first gate insulating layer 22 can be disposed over the active buffer layer 21 to cover the first active pattern 81. In an embodiment, the first gate insulating layer 22 can include a low hydrogen film having a hydrogen content lower than the threshold value. For example, the first gate insulating layer 22 can be formed of silicon oxide (SiOx).

A first gate electrode 82 of the first TFT 80 can be disposed over the first gate insulating layer 22. The first gate electrode 82 can overlap the channel region of the first active pattern 81. In addition or optionally, a capacitor bottom electrode 41 can be disposed over the first gate insulating layer 22 in the pixel area PIXA. In addition or optionally, a first pad layer 51 can be disposed over the first gate insulating layer 22 in the pad area PADA.

The first gate electrode 82, the capacitor bottom electrode 41 and the first pad layer 51 can be formed of the same material. The first gate electrode 82, the capacitor bottom electrode 41, and the first pad layer 51 can be formed of one of various metallic materials, such as molybdenum (Mo), aluminum (Al), chromium (Cr), gold (Au), titanium (Ti), nickel (Ni), neodymium (Nd), and copper (Cu), an alloy of one or more thereof, or multiple layers thereof, but are not limited thereto.

The interlayer insulating layer 23 can be disposed over the first gate insulating layer 22 to cover the first gate electrode 82, the capacitor bottom electrode 41, and the first pad layer 51. In an embodiment, the interlayer insulating layer 23 can be formed of a low hydrogen film having a hydrogen content lower than the threshold value. For example, the interlayer insulating layer 23 can be formed of silicon oxide (SiOx).

A first open area OP11 that penetrates the interlayer insulating layer 23, the first gate insulating layer 22, and the active buffer layer 21 to expose the stretchable area FA of the first substrate 10A can be provided. The first open area OP11 can expose a side surface of the interlayer insulating layer 23, a side surface of the first gate insulating layer 22, a side surface of the active buffer layer 21, and a portion of the first electrode 31.

A second electrode 32 of the second TFT 30 can be disposed over the interlayer insulating layer 23 above the first electrode 31. The second electrode 32 can be disposed adjacent to the first open area OP11. The second electrode 32 can be one of a source electrode or a drain electrode of the second TFT 30.

The capacitor top electrode 42 can be disposed over the interlayer insulating layer 23 in the pixel area PIXA. The capacitor top electrode 42 can be disposed to overlap the capacitor bottom electrode 41.

A fourth open area OP21 that penetrates the interlayer insulating layer 23 to expose the first pad layer 51 can be provided. The top surface of the first pad layer 51 and the side surface of the interlayer insulating layer 23 can be exposed by the fourth open area OP21. A second pad layer 52 can be disposed over the first pad layer 51 exposed by the fourth open area OP21. The second pad layer 52 can cover the top surface of the first pad layer 51 and the side surface of the interlayer insulating layer 23 exposed by the second open area OP12, and can be in direct contact with the first pad layer 51.

The second electrode 32 may, for example, be formed of a metal having a higher oxidizing power than the oxide semiconductor. For example, the second electrode 32 can be formed of at least one of Ti, Al, MoTi, ITO, IZO, or Zr. In another example, the second electrode 32 can be formed of a metal having a lower oxidizing power than the oxide semiconductor. For example, the second electrode 32 can be formed of at least one of Mo, Cu, W, or Fe. The capacitor top electrode 42 and the second pad layer 52 can be made of the same material as the second electrode 32.

The second active pattern 33 of the second TFT 30 can be disposed over the second electrode 32 and can extend to the first electrode 31 along the side surface of the interlayer insulating layer 23, the side surface of the first gate insulating layer 22, and the side surface of the active buffer layer 21 exposed by the first open area OP11. A top portion of the second active pattern 33 can be in contact with the top surface and the side surface of the second electrode 32, and a bottom portion of the second active pattern 33 can be in contact with the top surface of the first electrode 31.

A second gate insulating layer 34 can be disposed over the interlayer insulating layer 23 to cover the side surface of the interlayer insulating layer 23, the side surface of the first gate insulating layer 22, the side surface of the active buffer layer 21, and the second active pattern 33 exposed by the first open area OP11.

A source electrode 83, a drain electrode 84, a line (or a conductive line) 85, the second gate electrode 35, and the third pad layer 53 can be disposed over the second gate insulating layer 34.

The source electrode 83 and the drain electrode 84 can extend through the second gate insulating layer 34, the interlayer insulating layer 23, and the first gate insulating layer 22 to be connected to the source region and the drain region of the first active pattern 81, respectively.

The line 85 can be electrically connected to at least one of the components disposed in the pixel area PIXA.

The second gate electrode 35 can be disposed to overlap the second active pattern 33. A portion of the second gate electrode 35 can overlap the side surface of the insulating member 20 exposed by the first open area OP11 and a portion of the second active pattern 33 disposed over the first electrode 31, and another portion of the second gate electrode 35 can overlap another portion of the second active pattern 33 disposed over the second electrode 32.

The second gate insulating layer 34 can have a second open area OP12 exposing the stretchable area FA of the first substrate 10A. The second gate insulating layer 34 can have a fifth open area OP22 exposing the second pad layer 52. A portion of the top surface of the second pad layer 52 and a side surface of the second gate insulating layer 34 can be exposed by the fifth open area OP22.

A third pad layer 53 can be disposed over the second pad layer 52 exposed by the fifth open area OP22. The third pad layer 53 can cover the top surface of the second pad layer 52 and the side surface of the second gate insulating layer 34 exposed by the fifth open area OP22, and can be in direct contact with the second pad layer 52.

The second gate electrode 35 can be formed of the same material as the source electrode 83, the drain electrode 84, the line 85, and the third pad layer 53. The second gate electrode 35, the source electrode 83, the drain electrode 84, the line 85, and the third pad layer 53 can be formed of one of various metallic materials, such as molybdenum (Mo), aluminum (Al), chromium (Cr), gold (Au), titanium (Ti), nickel (Ni), neodymium (Nd), and copper (Cu), an alloy of one or more thereof, or multiple layers thereof, but are not limited thereto. A portion of the second gate electrode 35 can be disposed on the same layer as the source electrode 83 and the drain electrode 84.

The first active pattern 81, the first gate insulating layer 22, the first gate electrode 82, the source electrode 83, and the drain electrode 84 can form the first TFT 80. The first TFT 80 can have a coplanar structure.

The first electrode 31, the second electrode 32, the second active pattern 33, the second gate insulating layer 34, and the second gate electrode 35 can form the second TFT 30. The second TFT 30 can have a vertical structure. Each of the first TFT 80 and the second TFT 30 can be one of the driving transistor and the scanning transistor described with reference to FIG. 1.

The capacitor bottom electrode 41, the interlayer insulating layer 23, and the capacitor top electrode 42 can form a capacitor 30. The capacitor 30 can be a storage capacitor as described with reference to FIG. 1.

The first pad layer 51, the second pad layer 52, and the third pad layer 53 can form the pad 50. The pad 50 can be one of, but is not limited to, a gate pad for delivering a gate voltage to the subpixel, a data pad for delivering a data voltage to the subpixel, or a voltage pad for delivering a low potential voltage or a high potential voltage to the subpixel.

The passivation layer 60 can be disposed over the second gate insulating layer 34 to cover the source electrode 83 and the drain electrode 84, the line 85, the second gate electrode 35, and the third pad layer 53.

The passivation layer 60 can prevent moisture and oxygen from entering the first and second TFT 30. The passivation layer 60 can be formed of an inorganic material, and can be a single layer or multiple layers, but is not limited thereto.

The passivation layer 60 can have a third open area OP13 that exposes the stretchable area FA of the first substrate 10A. Around the stretchable area FA, a side surface of the passivation layer 60 can be exposed by the third open area OP13.

The passivation layer 60 can have a sixth open area OP23 exposing the third pad layer 53. Around the third pad layer 53, the side surface of the passivation layer 60 can be exposed by the sixth open area OP23.

A signal line 70 can be disposed on the passivation layer 60. The signal line 70 can be connected to line 85 through a contact hole that penetrates the passivation layer 60.

The signal line 70 can extend to the stretchable area FA of the first substrate 10A along the side surface of the passivation layer 60 exposed by the third open area OP13. In addition, the signal line 70 can extend to the pad area PADA and can be connected to the pad 50 through the sixth open area OP23 in the pad area PAD.

Embodiments of the present disclosure illustrate, but are not limited to, a case in which the stretchable area FA is disposed between the pixel area PIXA and the pad area PADA, and the signal line 70 connects the pixel area PIXA and the pad area PADA. The stretchable area FA can be disposed between neighboring pixel areas PIXA, and the signal line 70 can connect the neighboring pixel areas PIXA.

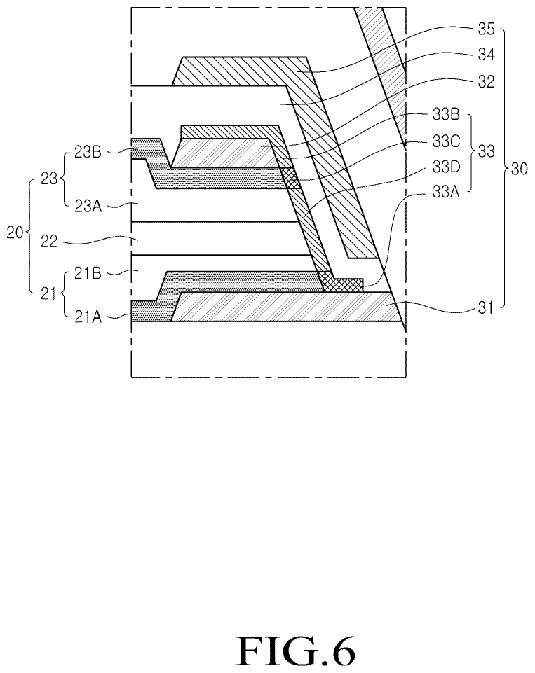

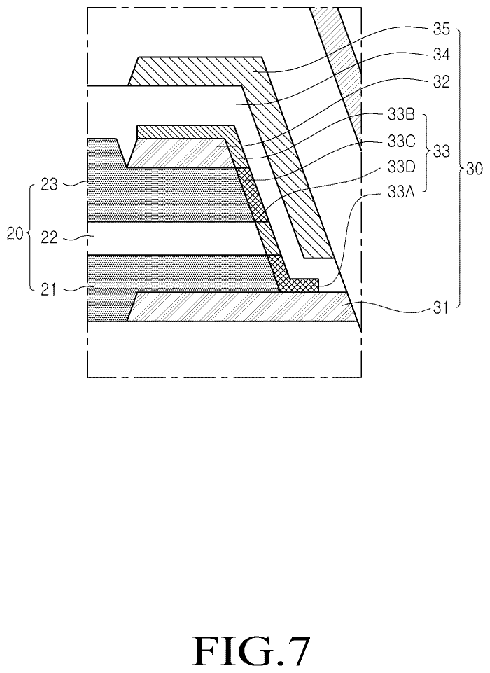

FIGS. 6 and 7 are cross-sectional views each illustrating a second TFT of an oxide semiconductor TFT array substrate included in a stretchable display device according to embodiments of the present disclosure.

Referring to FIG. 6, the second active pattern 33 of the second TFT 30 can include a first conductorization region 33A, a second conductorization region 33C, and a first oxide semiconductor region 33D.

The first conductorization region 33A can be disposed over the first electrode 31 and can be in direct contact with the first electrode 31.

The second conductorization region 33C can be disposed adjacent to the second electrode 32. The first oxide semiconductor region 33D can be disposed between the first conductorization region 33A and the second conductorization region 33C.

The first oxide semiconductor region 33D can have semiconductor properties. The first conductorization region 33A and the second conductorization region 33C can be regions in which the oxide semiconductor is conductorized by hydrogen diffused from the insulating member 20.

The insulating member 20 can include an active buffer layer 21, a first gate insulating layer 22, and an interlayer insulating layer 23.

The active buffer layer 21 can include a first level active buffer layer 21A disposed over the multi-buffer layer 11 and covering the first electrode 31 and a second level active buffer layer 21B disposed between the first level active buffer layer 21A and the first gate insulating layer 22.

The interlayer insulating layer 23 can include a first level interlayer insulating layer 23A disposed over the first gate insulating layer 22 and a second level interlayer insulating layer 23B disposed between the first level interlayer insulating layer 23A and the second gate insulating layer 34.

Each of the first level active buffer layer 21A, the second level active buffer layer 21B, the first gate insulating layer 22, the first level interlayer insulating layer 23A, and the second level interlayer insulating layer 23B can be formed of an insulating material, but the first level active buffer layer 21A and the second level interlayer insulating layer 23B can be formed of a material having a different hydrogen content than the second level active buffer layer 21B, the first gate insulating layer 22, and the first level interlayer insulating layer 23A. The first level active buffer layer 21A and the second level interlayer insulating layer 23B can be formed of a high hydrogen film material having a hydrogen content equal to or higher than a threshold value, and the second level active buffer layer 21B, the first gate insulating layer 22, and the first level interlayer insulating layer 23A can be formed of a low hydrogen film material having a hydrogen content lower than the threshold value. Each of the first level active buffer layer 21A and the second level interlayer insulating layer 23B can have a higher hydrogen content than the second level active buffer layer 21B, the first gate insulating layer 22, and the first level interlayer insulating layer 23A.

For example, the first level active buffer layer 21A and the second level interlayer insulating layer 23B can be formed of at least one selected from the group of materials including silicon nitride (SiNx), aluminum oxide (AlOx), hafnium oxide (HfOx), zirconium oxide (ZrOx), tantalum oxide (TaOx), or the like. The second level active buffer layer 21B, the first gate insulating layer 22, and the first level interlayer insulating layer 23A can be formed of silicon oxide (SiOx).

Here, the silicon nitride (SiNx) can be formed using silane (SiH₄) and ammonia (NH₃) as source gases. Aluminum oxide (AlOx) can be formed using trimethyl aluminum (TMA, C₃H₉A₁) as a source gas. Hafnium oxide (HfOx) can be formed using CpHf (C₁₁H₂₃N₃Hf) as a source gas. Zirconium oxide (ZrOx) can be formed using CpZr (C₁₁H₂₃N₃Zr) as a source gas. Tantalum oxide (TaOx) can be formed using CpTa (C₁₇H₃₉N₄Ta) as a source gas.

In response to the diffusion of hydrogen from the first level active buffer layer 21A, which is a high hydrogen film, the oxide semiconductor in a portion of the second active pattern 33 in contact with the side surface of the first level active buffer layer 21A can be conductorized, thereby forming the first conductorization region 33A. The first conductorization region 33A is a region that is conductorized by the diffusion of hydrogen contained in the first level active buffer layer 21A into the oxide semiconductor, and can contact the side surface of the first level active buffer layer 21A.

In response to the diffusion of hydrogen from the second level interlayer insulating layer 23B, which is a high hydrogen film, the oxide semiconductor in another portion of the second active pattern 33 in contact with the side surface of the second level interlayer insulating layer 23B can be conductorized, thereby forming the second conductorization region 33C. The second conductorization region 33C is a region that is conductorized by the diffusion of hydrogen contained in the second level interlayer insulating layer 23B into the oxide semiconductor, and can contact the side surface of the second level interlayer insulating layer 23B.

In another portion of the second active pattern 33 in contact with the side surfaces of low hydrogen films, such as the second level active buffer layer 21B, the first gate insulating layer 22, and the first level interlayer insulating layer 23A, the oxide semiconductor is not conductorized. Accordingly, the first oxide semiconductor region 33D can be in contact with the side surfaces of the second level active buffer layer 21B, the first gate insulating layer 22, and the first level interlayer insulating layer 23A

The second active pattern 33 can further include an extension region 33B. The extension region 33B can be disposed on the second electrode 32 and can be in direct contact with the second electrode 32. The extension region 33B can have different characteristics depending on the type of metallic material of the second electrode 32. The extension region 33B can be an oxide semiconductor region or a conductorization region in which an oxide semiconductor is conductorized.

In an example, the second electrode 32 can be formed of a metal having a higher oxidizing power than the oxide semiconductor. For example, the second electrode 32 can be formed of at least one of Ti, Al, MoTi, ITO, IZO, or Zr. In such a case, the metal of the second electrode 32 can be combined with the oxygen contained in the oxide semiconductor at the contact portion between the second electrode 32 and the oxide semiconductor, so that the oxide semiconductor can lose oxygen and be conductorized. In such a case, the extension region 33B can be a conductorization region. In another example, the second electrode 32 can be formed of a metal having a lower oxidizing power than the oxide semiconductor. For example, the second electrode 32 can be formed of at least one of Mo, Cu, W, or Fe. In such a case, the metal of the second electrode 32 may not be combined with the oxygen contained in the oxide semiconductor at the contact portion between the second electrode 32 and the oxide semiconductor, so that the oxide semiconductor can remain in the oxide semiconductor state without being conductorized. In such a case, the extension region 33B can be an oxide semiconductor region.

Referring to FIG. 7, each of the active buffer layer 21, the first gate insulating layer 22, and the interlayer insulating layer 23 can be formed of an insulating material, but the active buffer layer 21 and the interlayer insulating layer 23 can be formed of a material having a different hydrogen content than the first gate insulating layer 22. The active buffer layer 21 and the interlayer insulating layer 23 can be formed of a high hydrogen film material having a hydrogen content equal to or higher than the threshold value, and the first gate insulating layer 22 can be formed of a low hydrogen film material having a hydrogen content lower than the threshold value. The active buffer layer 21 and the interlayer insulating layer 23 can have a higher hydrogen content than the first gate insulating layer 22.

For example, the active buffer layer 21 and the interlayer insulating layer 23 can be formed of at least one selected from the group of materials including silicon nitride (SiNx), aluminum oxide (AlOx), hafnium oxide (HfOx), zirconium oxide (ZrOx), tantalum oxide (TaOx), or the like, and the first gate insulating layer 22 can be formed of silicon oxide (SiOx).

Here, the silicon nitride can be formed using silane (SiH₄) and ammonia (NH₃) as source gases. Aluminum oxide (AlOx) can be formed using trimethyl aluminum (TMA, C₃H₉Al) as a source gas. Hafnium oxide (HfOx) can be formed using CpHf (C₁₁H₂₃N₃Hf) as a source gas. Zirconium oxide (ZrOx) can be formed using CpZr (C₁₁H₂₃N₃Hf) as a source gas. Tantalum oxide (TaOx) can be formed using CpTa (C₁₇H₃₉N₄Ta) as a source gas.

In response to the diffusion of hydrogen from the active buffer layer 21, which is a high hydrogen film, the oxide semiconductor in a portion of the second active pattern 33 in contact with the side surface of the active buffer layer 21 can be conductorized, thereby forming the first conductorization region 33A. The first conductorization region 33A is a region that is conductorized by the diffusion of hydrogen contained in the active buffer layer 21 into the oxide semiconductor, and can contact the side surface of the active buffer layer 21.

In response to the diffusion of hydrogen from the interlayer insulating layer 23, which is a high hydrogen film, the oxide semiconductor in another portion of the second active pattern 33 in contact with the side surface of the interlayer insulating layer 23 can be conductorized, thereby forming the second conductorization region 33C. The second conductorization region 33C is a region that is conductorized by the diffusion of hydrogen contained in the interlayer insulating layer 23 into the oxide semiconductor, and can contact the side surface of the interlayer insulating layer 23.

In another portion of the second active pattern 33 in contact with the side surface of the first gate insulating layer 22, which is a low hydrogen film, the oxide semiconductor is not conductorized. Accordingly, the first oxide semiconductor region 33D can be in contact with the side surface of the first gate insulating layer 22.

In the embodiment illustrated with reference to FIG. 6, the active buffer layer 21 has a structure in which a high hydrogen film and a low hydrogen film are stacked sequentially and the interlayer insulating layer 23 has a structure in which a low hydrogen film and a high hydrogen film are stacked sequentially, and in the embodiment illustrated with reference to FIG. 7, the active buffer layer 21 and the interlayer insulating layer 23 are implemented as a high hydrogen film, but this is not intended to be limiting.

The active buffer layer 21 can have a structure in which a high hydrogen film and a low hydrogen film are stacked sequentially and the interlayer insulating layer 23 can have a single-layer structure of a high hydrogen film, or the active buffer layer 21 can have a single-layer structure of a high hydrogen film and the interlayer insulating layer 23 can have a structure in which a low hydrogen film and a high hydrogen film are stacked sequentially. In other words, the active buffer layer 21 can have a structure in which a high hydrogen film and a low hydrogen film are stacked sequentially or a single-layer structure of a high hydrogen film, and the interlayer insulating layer 23 can have a structure in which a low hydrogen film and a high hydrogen film are stacked sequentially or a single-layer structure of a high hydrogen film.

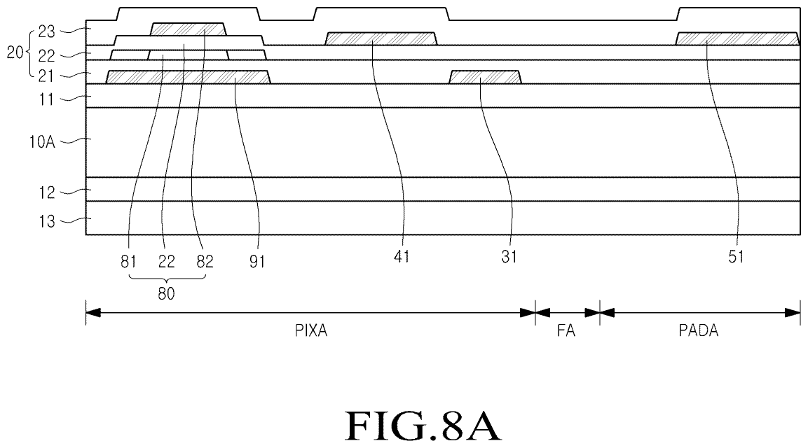

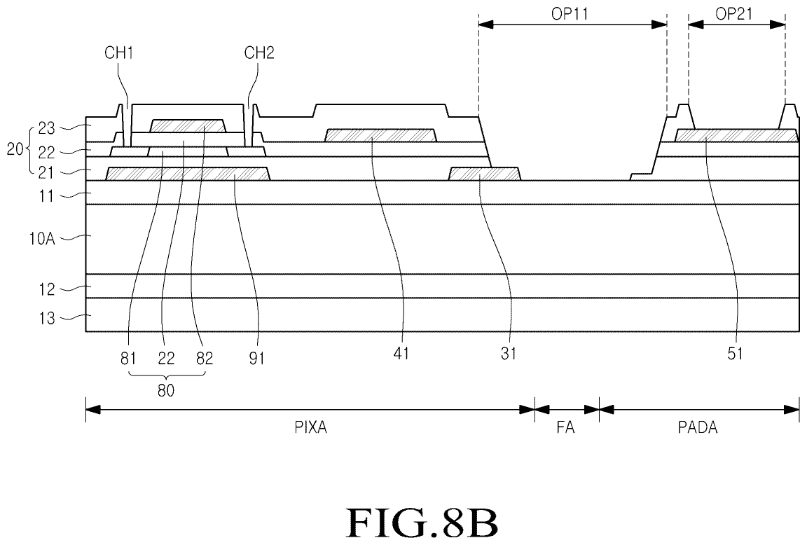

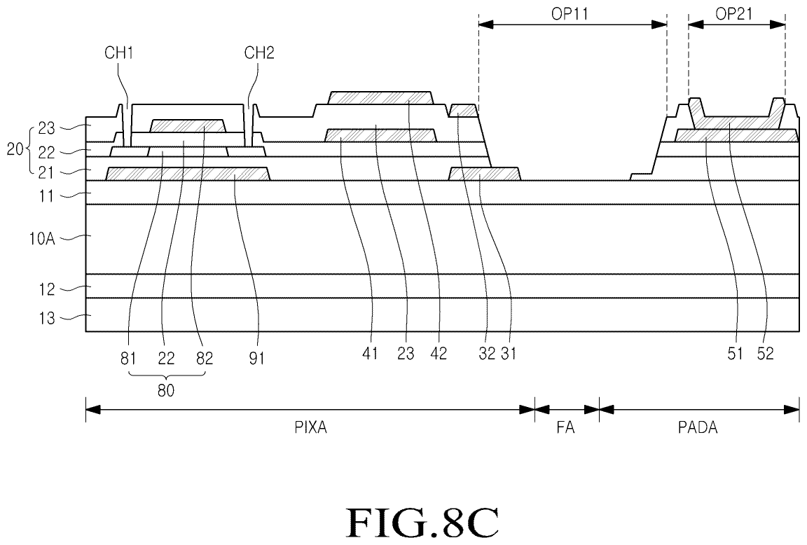

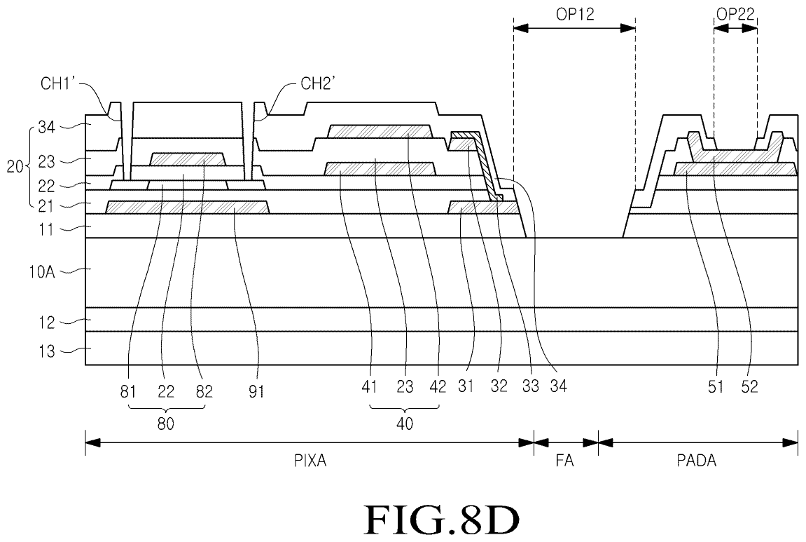

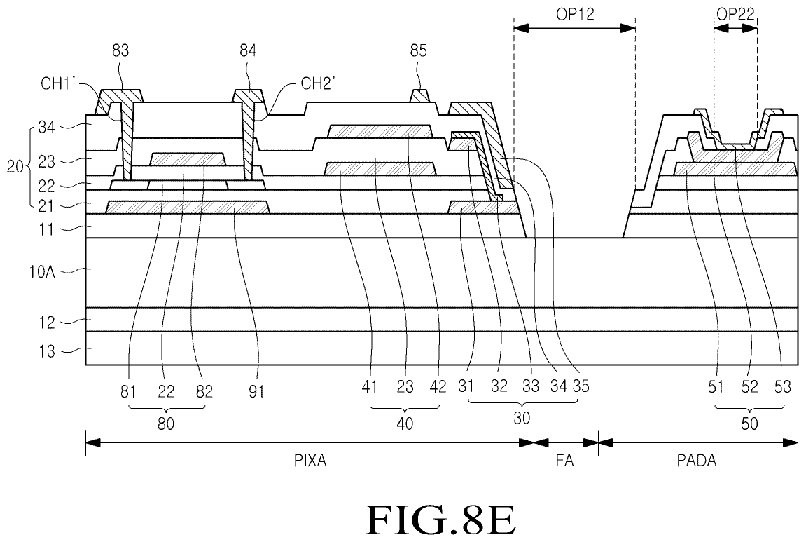

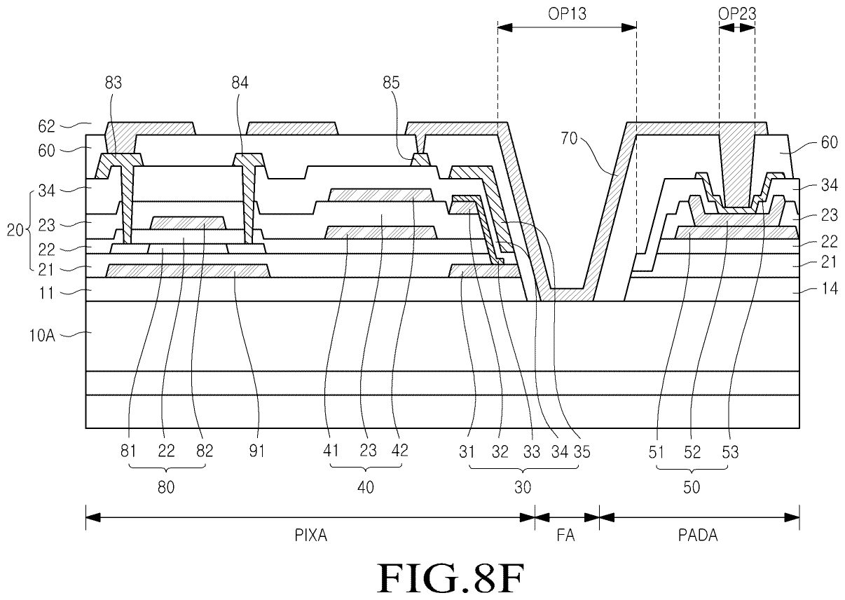

FIGS. 8A to 8F are cross-sectional views illustrating a method of manufacturing an oxide semiconductor TFT array substrate included in a stretchable display device according to embodiments of the present disclosure, and illustrate a method of manufacturing the oxide semiconductor TFT array substrate shown in FIG. 5.

Referring to FIG. 8A, a sacrificial layer 12, a first substrate 10A, and a multi-buffer layer 11 can be formed sequentially over a support substrate 13, and a first electrode 31 of a second TFT can be formed over the multi-buffer layer 11 in a pixel area PIXA. In addition or optionally, a bottom shield metal pattern 91 can be further formed over the multi-buffer layer 11 in the pixel area PIXA. The support substrate 13 can serve to support the first substrate 10A during the manufacturing process. The sacrificial layer 12 can bond the support substrate 13 and the first substrate 10A together. The sacrificial layer 12 can be formed of an adhesive material, the adhesion of which can be reduced by at least one of a chemical treatment or an optical treatment. After completion of the manufacturing process, the adhesion of the sacrificial layer 12 can be reduced, and the sacrificial layer 12 and the support substrate 13 can be removed.

The first electrode 31 and the bottom shield metal pattern 91 can be formed together. The first electrode 31 and the bottom shield metal pattern 91 can be formed of the same material.

An active buffer layer 21 covering the first electrode 31 and the bottom shield metal pattern 91 can be formed over the multi-buffer layer 11. In an embodiment, the active buffer layer 21 can be implemented as a low hydrogen film having a hydrogen content lower than a threshold value. In another embodiment, the active buffer layer 21 can have a structure in which a high hydrogen film having a hydrogen content equal to or higher than the threshold value and a low hydrogen film having a hydrogen content lower than a threshold are stacked sequentially. In another embodiment, the active buffer layer 21 can have a single-layer structure of a high hydrogen film having a hydrogen content equal to or higher than the threshold value. The high hydrogen film can be formed of at least one selected from the group of materials including silicon nitride (SiNx), aluminum oxide (AlOx), hafnium oxide (HfOx), zirconium oxide (ZrOx), tantalum oxide (TaOx), or the like. The hydrogen film can be formed of silicon oxide (SiOx).

The first active pattern 81 of the first TFT 80 can be formed over the active buffer layer 21 in the pixel area PIXA. In an example, the first active pattern 81 can be formed of an oxide semiconductor. In another example, the first active pattern 81 can be formed of amorphous silicon (a-Si), polycrystalline silicon (poly-Si), an organic semiconductor, or the like.

A first gate insulating layer 22 covering the first active pattern 81 can be formed over the active buffer layer 21. The first gate insulating layer 22 can be implemented as a low hydrogen film. The first gate insulating layer 22 can include silicon oxide (SiOx).

A first gate electrode 82 can be formed over the first gate insulating layer 22 in the pixel area PIXA to overlap a channel region of the first active pattern 81. In addition or optionally, a capacitor bottom electrode 41 can be formed over the first gate insulating layer 22 in the pixel area PIXA. In addition or optionally, a first pad layer 51 can be formed over the first gate insulating layer 22 in a pad area PADA.

The first gate electrode 82, the capacitor bottom electrode 41, and the first pad layer 51 can be formed at one time. The first gate electrode 82, the capacitor bottom electrode 41, and the first pad layer 51 can be formed of the same material.

An interlayer insulating layer 23 can be formed over the first gate insulating layer 22 to cover the first gate electrode 82, the capacitor bottom electrode 41, and the first pad layer 51.

In an embodiment, the interlayer insulating layer 23 can be implemented as a low hydrogen film having a hydrogen content lower than the threshold value. In another embodiment, the interlayer insulating layer 23 can have a structure in which a low hydrogen film having a hydrogen content lower than the threshold value and a high hydrogen film having a hydrogen content higher than the threshold value are stacked sequentially. In another embodiment, the interlayer insulating layer 23 can be implemented as a single layer of a high hydrogen film having a hydrogen content higher than the threshold value. The high hydrogen film can be formed of at least one selected from the group of materials including silicon nitride (SiNx), aluminum oxide (AlOx), hafnium oxide (HfOx), zirconium oxide (ZrOx), tantalum oxide (TaOx), or the like. The hydrogen film can include silicon oxide (SiOx).

The active buffer layer 21, the first gate insulating layer 22, and the interlayer insulating layer 23 can form the insulating member 20.

Referring to FIG. 8B, a first open area OP11 that penetrates a side surface of the interlayer insulating layer 23, a side surface of the first gate insulating layer 22, and the active buffer layer 21 can be formed to expose the stretchable area FA of the multi-buffer layer 11. The first open area OP11 can be formed to expose a portion of the first electrode 31. Through the first open area OP11, the side surface of the interlayer insulating layer 23, a side surface of the first gate insulating layer 22, and a side surface of the active buffer layer 21 can be exposed.

The interlayer insulating layer 23 can be formed to extend through a fourth open area OP21 to expose the first pad layer 51. Through the fourth open area OP21, the top surface of the first pad layer 51 and the side surface of the interlayer insulating layer 23 can be exposed.

In addition, a first preliminary contact hole CH1 and a second preliminary contact hole CH2 that penetrate the interlayer insulating layer 23 and the first gate insulating layer 22 can be formed to expose a source region and a drain region of the first active pattern 81.

Referring to FIG. 8C, a capacitor top electrode 42, a second electrode 32, and a second pad layer 52 can be formed over the interlayer insulating layer 23.

The capacitor top electrode 42 can be provided to overlap the capacitor bottom electrode 41. The second electrode 32 can be disposed in the periphery of the first open area OP11. The second pad layer 52 can be formed over the top surface of the first pad layer 51 and the side surface of the interlayer insulating layer 23 exposed by the fourth open area OP21.

In an example, the second electrode 32 can be formed of a metal having a higher oxidizing power than the oxide semiconductor. For example, the second electrode 32 can include at least one of Ti, Al, MoTi, ITO, IZO, or Zr. In another example, the second electrode 32 can be formed of a metal having a lower oxidizing power than the oxide semiconductor. For example, the second electrode 32 can include at least one of Mo, Cu, W, or Fe. The capacitor top electrode 42 and the second pad layer 52 can be formed of the same material as the second electrode 32.

Referring to FIG. 8D, after a second active pattern 33 and a second gate insulating layer 34 are formed, a second open area OP12, a fifth open area OP22, a first contact hole CH1′, and a second contact hole CH2′ can be formed.

The second active pattern 33 can be disposed over the second electrode 32 and extend to the first electrode 31 along the side surface of the interlayer insulating layer 23, the side surface of the first gate insulating layer 22, and the side surface of the active buffer layer 21 exposed by the first open area OP11. The top portion of the second active pattern 33 can be disposed over the second electrode 32 to directly contact the second electrode 32. The bottom portion of the second active pattern 33 can be disposed over the first electrode 31 to directly contact the first electrode 31. In an embodiment, the second active pattern 33 can be formed of an oxide semiconductor. In another embodiment, the second active pattern 33 can include a conductorization region.

A second gate insulating layer 34 can be disposed over the interlayer insulating layer 23 to cover the second active pattern 33.

The second open area OP12 that penetrates the second gate insulating layer 34 and the multi-buffer layer 11 can be formed to expose the stretchable area FA of the first substrate 10A. The fifth open area OP22 that penetrates the second gate insulating layer 34 can be formed to expose the second pad layer 52. The top surface of the second pad layer 52 and the side surface of the second gate insulating layer 34 can be exposed by the fifth open area OP22.

The first contact hole CH1′ that penetrates the second gate insulating layer 34 can be formed to be connected to the first spare contact hole CH1. The second contact hole CH2′ that penetrates the second gate insulating layer 34 can be formed to be connected to the second spare contact hole CH2.

Referring to FIG. 8E, a source electrode 83, a drain electrode 84, a line 85, a second gate electrode 35, and a third pad layer 53 can be formed over the second gate insulating layer 34.

The source electrode 83 can be connected to the source region of the first active pattern 81 through the first contact hole CH1′. The drain electrode 84 can be connected to the drain region of the first active pattern 81 through the second contact hole CH2′.

The second gate electrode 35 can be formed to overlap the second active pattern 33. The second gate electrode 35 can be formed such that a portion thereof overlaps the side surface of the insulating member 20 exposed by the first open area OP11 and a portion of the second active pattern 33 disposed over the first electrode 31 and another portion thereof overlaps another portion of the second active pattern 33 disposed over the second electrode 32.

The line 85 can be disposed in the pixel area PIXA, and can be electrically connected to a component disposed in the pixel area PIXA. The third pad layer 53 can be formed to cover the top surface of the second pad layer 52 and the side surface of the second gate insulating layer 34 exposed by the fifth open area OP22.

The source electrode 83, the drain electrode 84, the line 85, the second gate electrode 35, and the third pad layer 53 can be formed at one time. The source electrode 83, the drain electrode 84, the line 85, the second gate electrode 35, and the third pad layer 53 can be formed of the same material.

Referring to FIG. 8F, a passivation layer 60 covering the source electrode 83, the drain electrode 84, the second gate electrode 35, the line 85, and the third pad layer 53 can be formed over the second gate insulating layer 34.

Thereafter, a third open area OP13 penetrating the passivation layer 60 to expose the stretchable area FA of the first substrate 10A and a sixth open area OP23 exposing the third pad layer 53 can be formed. In addition, a contact hole exposing the line 85 can be formed.

Thereafter, a signal line 70 can be formed. The signal line 70 can be connected to a line 85 through a contact hole exposing the line 85 and extend to the stretchable area FA of the first substrate 10A along a side surface of the passivation layer 60 exposed by the third open area OP13. In addition, the signal line 70 can extend to a pad area PADA and be connected to the third pad layer 53 through the sixth open area OP23.

A case in which the oxide semiconductor TFT array substrate is used in a stretchable display device has been described hereinabove, this is not intended to be limiting. The oxide semiconductor TFT array substrate according to embodiments of the present disclosure can also be used in a non-stretchable display device. In such cases, the areas exposed by the first, second, and third open areas OP11, OP12, and OP13 in FIGS. 3, 5, and 8A through 8F may not be stretchable areas.

The oxide semiconductor TFT array substrate and the stretchable display device including the same according to embodiments of the present disclosure described above can be briefly reviewed as follows.

A stretchable display device according to embodiments of the present disclosure includes a substrate including a pixel area and a stretchable area; an insulating member disposed over the substrate in the pixel area and including a first open area exposing the stretchable area; and a TFT disposed over an area including a side surface of the insulating member exposed by the first open area.

According to embodiments of the present disclosure, the TFT can include a first electrode disposed over the substrate in the pixel area, with at least a portion thereof being exposed by the first open area; a second electrode disposed over the insulating member above the first electrode to be adjacent to the first open area; an active pattern disposed over the second electrode and extending to the first electrode along the side surface of the insulating member exposed by the first open area; a gate insulating layer disposed over the insulating member, covering the active pattern, and including a second open area exposing the stretchable area; and a gate electrode disposed over the gate insulating layer to overlap the active pattern.

According to embodiments of the present disclosure, the active pattern can include an oxide semiconductor, and includes a first conductorization region in contact with the first electrode; a second conductorization region adjacent to the second electrode; and a first oxide semiconductor region between the first conductorization region and the second conductorization region.

According to embodiments of the present disclosure, the active pattern can further include a third conductorization region in contact with the second electrode and the second conductorization region.

According to embodiments of the present disclosure, the second electrode can include a metal having a higher oxidizing power than the oxide semiconductor.

According to embodiments of the present disclosure, the second electrode can include at least one of Ti, Al, MoTi, ITO, IZO, or Zr.

According to embodiments of the present disclosure, the active pattern can further include a second oxide semiconductor region in contact with the second electrode and the second conductorization region.

According to embodiments of the present disclosure, the second electrode can include a metal having a lower oxidizing power than the oxide semiconductor.

According to embodiments of the present disclosure, the second electrode can include at least one of Mo, Cu, W, or Fe.

According to embodiments of the present disclosure, the insulating member can include a first insulating layer disposed over the substrate; a second insulating layer disposed over the first insulating layer and having a lower hydrogen content than the first insulating layer; and a third insulating layer disposed over the second insulating layer and having a higher hydrogen content than the second insulating layer, wherein a side surface of the first insulating layer is in contact with the first conductorization region of the active pattern, a side surface of the second insulating layer is in contact with the first oxide semiconductor region of the active pattern, and a side surface of the third insulating layer is in contact with the second conductorization region of the active pattern.

According to embodiments of the present disclosure, each of the first insulating layer and the third insulating layer can include at least one selected from a group including silicon nitride (SiNx), aluminum oxide (AlOx), hafnium oxide (HfOx), zirconium oxide (ZrOx), or tantalum oxide (TaOx), and the second insulating layer can include silicon oxide (SiOx).

According to embodiments of the present disclosure, the stretchable display device can further include a passivation layer disposed over the gate insulating layer, covering the gate electrode, and including a third open area exposing the stretchable area; and a signal line disposed over the passivation layer and extending to the stretchable area along a side surface of the passivation layer exposed by the third open area.

A stretchable display device according to embodiments of the present disclosure includes a substrate including a pixel area, a stretchable area, and a pad area; a buffer layer disposed over the substrate; a first active pattern disposed over the pixel area of the buffer layer, a first gate insulating layer disposed over the buffer layer and covering the first active pattern; a first gate electrode disposed over the first gate insulating layer to overlap a portion of the first active pattern; an interlayer insulating layer disposed over the first gate insulating layer and covering the first gate electrode; a first open area penetrating the interlayer insulating layer, the first gate insulating layer, and the buffer layer to expose the stretchable area of the substrate; a first electrode disposed over the pixel area of the substrate, with at least a portion thereof being exposed by the first open area; a second electrode disposed over the interlayer insulating layer above the first electrode to be adjacent to the first open area; a second active pattern disposed over the second electrode and extending to the first electrode along a side surface of the interlayer insulating layer, a side surface of the first gate insulating layer, and a side surface of the buffer layer exposed by the first open area; a second gate insulating layer disposed over the interlayer insulating layer, covering the second active pattern, and including a second open area exposing the stretchable area of the substrate; and a second gate electrode disposed over the second gate insulating layer to overlap the second active pattern.

According to embodiments of the present disclosure, the second active pattern can include an oxide semiconductor, and can include a first conductorization region in contact with the first electrode; a second conductorization region adjacent to the second electrode; and a first oxide semiconductor region between the first conductorization region and the second conductorization region.

According to embodiments of the present disclosure, the second active pattern can further include a third conductorization region in contact with the second electrode and the second conductorization region.

According to embodiments of the present disclosure, the second electrode can include a metal having a higher oxidizing power than the oxide semiconductor.

According to embodiments of the present disclosure, the second electrode can include at least one of Ti, Al, MoTi, ITO, IZO, or Zr.

According to embodiments of the present disclosure, the second active pattern can further include a second oxide semiconductor region in contact with the second electrode and the second conductorization region.

According to embodiments of the present disclosure, the second electrode can include a metal having a lower oxidizing power than the oxide semiconductor.

According to embodiments of the present disclosure, the second electrode can include at least one of Mo, Cu, W, or Fe.

According to embodiments of the present disclosure, the buffer layer can include a first level buffer layer disposed over the first electrode and the substrate and having a higher hydrogen content than the first gate insulating layer; and a second level buffer layer disposed between the first level buffer layer and the first gate insulating layer and having a lower hydrogen content than the first level buffer layer. A side surface of the first level buffer layer can be in contact with the first conductorization region of the second active pattern, and a side surface of the second level buffer layer and a side surface of the first gate insulating layer can be in contact with the first oxide semiconductor region of the second active pattern.

According to embodiments of the present disclosure, the interlayer insulating layer can include a first level interlayer insulating layer disposed over the first gate insulating layer; and a second level interlayer insulating layer disposed between the first level interlayer insulating layer and the second gate insulating layer, and having a higher hydrogen content than the first gate insulating layer and the first level interlayer insulating layer. The side surface of the first gate insulating layer and a side surface of the first level interlayer insulating layer can be in contact with the first oxide semiconductor region of the second active pattern. A side surface of the second level interlayer insulating layer can be in contact with the second conductorization region of the second active pattern.

According to embodiments of the present disclosure, the hydrogen content of the buffer layer can be higher than the hydrogen content of the first gate insulating layer, the side surface of the buffer layer can be in contact with the first conductorization region of the second active pattern, and the side surface of the first gate insulating layer can be in contact with the first oxide semiconductor region of the second active pattern.

According to embodiments of the present disclosure, the hydrogen content of the interlayer insulating layer can be higher than the hydrogen content of the first gate insulating layer, the side surface of the interlayer insulating layer can be in contact with the second conductorization region of the second active pattern, and the side surface of the first gate insulating layer can be in contact with the first oxide semiconductor region of the second active pattern.

According to embodiments of the present disclosure, the stretchable display device can further include a bottom shield metal pattern disposed over the substrate and overlapping the first active pattern. The first electrode can include the same material as the bottom shield metal pattern.

According to embodiments of the present disclosure, the stretchable display device can further include a capacitor bottom electrode disposed over the first gate insulating layer; and a capacitor top electrode disposed over the interlayer insulating layer and overlapping the capacitor bottom electrode. The second electrode can include the same material as the capacitor top electrode.

According to embodiments of the present disclosure, the stretchable display device can further include a capacitor bottom electrode disposed over the first gate insulating layer; and a capacitor top electrode disposed over the interlayer insulating layer and overlapping the capacitor bottom electrode. The first gate electrode includes the same material as the capacitor bottom electrode.

According to embodiments of the present disclosure, the stretchable display device can further include a source electrode disposed over the second gate insulating layer and connected to a source region of the first active pattern through a first contact hole penetrating the second gate insulating layer, the interlayer insulating layer, and the first gate insulating layer; and a drain electrode disposed over the second gate insulating layer and connected to a drain region of the first active pattern through a second contact hole penetrating the second gate insulating layer, the interlayer insulating layer, and the first gate insulating layer. The second gate electrode can include the same material as the source electrode and the drain electrode.

According to embodiments of the present disclosure, the stretchable display device can further include a source electrode disposed over the second gate insulating layer and connected to a source region of the first active pattern through a first contact hole penetrating the second gate insulating layer, the interlayer insulating layer, and the first gate insulating layer, and a drain electrode disposed over the second gate insulating layer and connected to a drain region of the first active pattern through a second contact hole penetrating the second gate insulating layer, the interlayer insulating layer, and the first gate insulating layer. A portion of the second gate electrode can be disposed on the same layer as the source electrode and the drain electrode.

According to embodiments of the present disclosure, the stretchable display device can further include a pad disposed in the pad area. The pad can include a first pad layer disposed over the first gate insulating layer, and a second pad layer disposed over the first pad layer exposed by a third open area penetrating the interlayer insulating layer.

According to embodiments of the present disclosure, the second electrode can include the same material as the second pad layer.

According to embodiments of the present disclosure, the pad can further include a third pad layer disposed over the second pad layer exposed by a fourth open area penetrating the second gate insulating layer. The second gate electrode can include the same material as the third pad layer.

A TFT array substrate according to embodiments of the present disclosure includes a buffer layer disposed over a substrate; a first gate insulating layer disposed over the buffer layer, an interlayer insulating layer disposed over the first gate insulating layer; a first open area penetrating the interlayer insulating layer, the first gate insulating layer, and the buffer layer to expose a portion of the substrate; a first TFT; and a second TFT. The first TFT can include a first oxide semiconductor pattern disposed over the buffer layer and covered with the first gate insulating layer; the first gate insulating layer, and a first gate electrode disposed over the first gate insulating layer to overlap a portion of the first oxide semiconductor pattern. The second TFT can include a first electrode disposed over the substrate, with at least a portion thereof being exposed by the first open area; a second electrode disposed over the interlayer insulating layer above the first electrode to be adjacent to the first open area; a second oxide semiconductor pattern disposed over the second electrode, and extending to the first electrode along a side surface of the interlayer insulating layer, a side surface of the first gate insulating layer, and a side surface of the buffer layer exposed by the first open area; a second gate insulating layer disposed over the interlayer insulating layer and covering the second oxide semiconductor pattern; and a second gate electrode disposed over the second gate insulating layer to overlap the second oxide semiconductor pattern.

According to embodiments of the present disclosure having the above-described structure, in the oxide semiconductor TFT array substrate and the stretchable display device including the same, a TFT can be disposed on a side surface of the insulating member exposed by the first open area exposing the stretchable region to reduce the area occupied by the TFT, thereby reducing the size of the pixel area and improving resolution.

According to embodiments of the present disclosure, in the oxide semiconductor TFT array substrate and the stretchable display device including the same, the size of the pixel area can be reduced by reducing the area occupied by the TFT, and the free area resulting from the reduced pixel area can be used as a stretchable area to improve stretching characteristics.

According to embodiments of the present disclosure, in the oxide semiconductor TFT array substrate and the stretchable display device including the same, the impact of stretching stress on the TFT can be reduced to reduce damage to the TFT and reduce or prevent characteristics deterioration of the TFT.

According to embodiments of the present disclosure, in the oxide semiconductor TFT array substrate and the stretchable display device including the same, the oxide semiconductor can be conductorized by diffusing ions contained in the insulating member to form a conductorization region, thereby reducing the number of process steps. Accordingly, the effect of process optimization can be obtained.

The above description has been presented to enable any person skilled in the art to make and use the technical idea of the present disclosure, and has been provided in the context of a particular application and its requirements. Various modifications, additions and substitutions to the described embodiments of the present disclosure will be readily apparent to those skilled in the art, and the general principles defined herein can be applied to other embodiments of the present disclosure and applications without departing from the spirit and scope of the present disclosure. The above description and the accompanying drawings provide an example of the technical idea of the present disclosure for illustrative purposes only. That is, the disclosed embodiments are intended to illustrate the scope of the technical idea of the present disclosure.

What is claimed is:

1. A stretchable display device comprising:
a substrate comprising a pixel area and a stretchable area;
an insulating member disposed over the substrate in the pixel area and comprising a first open area exposing the stretchable area; and
a thin-film transistor disposed over an area including a side surface of the insulating member exposed by the first open area.

2. The stretchable display device of claim 1, wherein the thin-film transistor comprises:
a first electrode disposed over the substrate in the pixel area, with at least a portion of the first electrode being exposed by the first open area;
a second electrode disposed over the insulating member above the first electrode to be adjacent to the first open area;
an active pattern disposed over the second electrode and extending to the first electrode along the side surface of the insulating member exposed by the first open area;
a gate insulating layer disposed over the insulating member, covering the active pattern, and comprising a second open area exposing the stretchable area; and
a gate electrode disposed over the gate insulating layer to overlap the active pattern.

3. The stretchable display device of claim 2, wherein the active pattern comprises an oxide semiconductor, and comprises:
a first conductorization region in contact with the first electrode;
a second conductorization region adjacent to the second electrode; and
a first oxide semiconductor region between the first conductorization region and the second conductorization region.

4. The stretchable display device of claim 3, wherein the active pattern further comprises a third conductorization region in contact with the second electrode and the second conductorization region.

5. The stretchable display device of claim 4, wherein the second electrode comprises a metal having a higher oxidizing power than the oxide semiconductor.

6. The stretchable display device of claim 4, wherein the second electrode comprises at least one of Ti, Al, MoTi, ITO, IZO, or Zr.

7. The stretchable display device of claim 3, wherein the active pattern further comprises a second oxide semiconductor region in contact with the second electrode and the second conductorization region.

8. The stretchable display device of claim 7, wherein the second electrode comprises a metal having a lower oxidizing power than the oxide semiconductor.

9. The stretchable display device of claim 7, wherein the second electrode comprises at least one of Mo, Cu, W, or Fe.

10. The stretchable display device of claim 3, wherein the insulating member comprises:
a first insulating layer disposed over the substrate;
a second insulating layer disposed over the first insulating layer and having a lower hydrogen content than the first insulating layer, and
a third insulating layer disposed over the second insulating layer and having a higher hydrogen content than the second insulating layer,
wherein a side surface of the first insulating layer is in contact with the first conductorization region of the active pattern, a side surface of the second insulating layer is in contact with the first oxide semiconductor region of the active pattern, and a side surface of the third insulating layer is in contact with the second conductorization region of the active pattern.

11. The stretchable display device of claim 10, wherein each of the first insulating layer and the third insulating layer comprises at least one selected from a group including silicon nitride (SiNx), aluminum oxide (AlOx), hafnium oxide (HfOx), zirconium oxide (ZrOx), or tantalum oxide (TaOx), and
wherein the second insulating layer comprises silicon oxide (SiOx).

12. The stretchable display device of claim 2, further comprising:
a passivation layer disposed over the gate insulating layer, covering the gate electrode, and comprising a third open area exposing the stretchable area; and
a signal line disposed over the passivation layer and extending to the stretchable area along a side surface of the passivation layer exposed by the third open area.

13. A stretchable display device comprising:
a substrate comprising a pixel area, a stretchable area, and a pad area;
a buffer layer disposed over the substrate;
a first active pattern disposed over the pixel area of the buffer layer;
a first gate insulating layer disposed over the buffer layer and covering the first active pattern;
a first gate electrode disposed over the first gate insulating layer to overlap a portion of the first active pattern;
an interlayer insulating layer disposed over the first gate insulating layer and covering the first gate electrode;
a first open area penetrating the interlayer insulating layer, the first gate insulating layer, and the buffer layer to expose the stretchable area of the substrate;
a first electrode disposed over the pixel area of the substrate, with at least a portion of the first electrode being exposed by the first open area;
a second electrode disposed over the interlayer insulating layer above the first electrode to be adjacent to the first open area;
a second active pattern disposed over the second electrode and extending to the first electrode along a side surface of the interlayer insulating layer, a side surface of the first gate insulating layer, and a side surface of the buffer layer exposed by the first open area;
a second gate insulating layer disposed over the interlayer insulating layer, covering the second active pattern, and comprising a second open area exposing the stretchable area of the substrate; and
a second gate electrode disposed over the second gate insulating layer to overlap the second active pattern.

14. The stretchable display device of claim 13, wherein the second active pattern comprises an oxide semiconductor, and comprises:
a first conductorization region in contact with the first electrode;
a second conductorization region adjacent to the second electrode; and
a first oxide semiconductor region between the first conductorization region and the second conductorization region.

15. The stretchable display device of claim 14, wherein the second active pattern further comprises a third conductorization region in contact with the second electrode and the second conductorization region.

16. The stretchable display device of claim 15, wherein the second electrode comprises a metal having a higher oxidizing power than the oxide semiconductor.

17. The stretchable display device of claim 15, wherein the second electrode comprises at least one of Ti, Al, MoTi, ITO, IZO, or Zr.

18. The stretchable display device of claim 14, wherein the second active pattern further comprises a second oxide semiconductor region in contact with the second electrode and the second conductorization region.

19. The stretchable display device of claim 18, wherein the second electrode comprises a metal having a lower oxidizing power than the oxide semiconductor.

20. The stretchable display device of claim 18, wherein the second electrode comprises at least one of Mo, Cu, W, or Fe.

21. The stretchable display device of claim 14, wherein the buffer layer comprises:
a first level buffer layer disposed over the first electrode and the substrate and having a higher hydrogen content than the first gate insulating layer; and
a second level buffer layer disposed between the first level buffer layer and the first gate insulating layer and having a lower hydrogen content than the first level buffer layer,
wherein a side surface of the first level buffer layer is in contact with the first conductorization region of the second active pattern, and
wherein a side surface of the second level buffer layer and a side surface of the first gate insulating layer are in contact with the first oxide semiconductor region of the second active pattern.

22. The stretchable display device of claim 14, wherein the interlayer insulating layer comprises:
a first level interlayer insulating layer disposed over the first gate insulating layer, and
a second level interlayer insulating layer disposed between the first level interlayer insulating layer and the second gate insulating layer, and having a higher hydrogen content than the first gate insulating layer and the first level interlayer insulating layer,
wherein the side surface of the first gate insulating layer and a side surface of the first level interlayer insulating layer are in contact with the first oxide semiconductor region of the second active pattern, and
wherein a side surface of the second level interlayer insulating layer is in contact with the second conductorization region of the second active pattern.

23. The stretchable display device of claim 14, wherein the hydrogen content of the buffer layer is higher than the hydrogen content of the first gate insulating layer,
wherein the side surface of the buffer layer is in contact with the first conductorization region of the second active pattern, and
wherein the side surface of the first gate insulating layer is in contact with the first oxide semiconductor region of the second active pattern.

24. The stretchable display device of claim 14, wherein the hydrogen content of the interlayer insulating layer is higher than the hydrogen content of the first gate insulating layer,
wherein the side surface of the interlayer insulating layer is in contact with the second conductorization region of the second active pattern, and
wherein the side surface of the first gate insulating layer is in contact with the first oxide semiconductor region of the second active pattern.

25. The stretchable display device of claim 13, further comprising a bottom shield metal pattern disposed over the substrate and overlapping the first active pattern,
wherein the first electrode comprises a same material as the bottom shield metal pattern.

26. The stretchable display device of claim 13, further comprising:
a capacitor bottom electrode disposed over the first gate insulating layer; and
a capacitor top electrode disposed over the interlayer insulating layer and overlapping the capacitor bottom electrode,
wherein the second electrode comprises a same material as the capacitor top electrode.

27. The stretchable display device of claim 13, further comprising:
a capacitor bottom electrode disposed over the first gate insulating layer; and
a capacitor top electrode disposed over the interlayer insulating layer and overlapping the capacitor bottom electrode,
wherein the first gate electrode comprises a same material as the capacitor bottom electrode.

28. The stretchable display device of claim 13, further comprising:
a source electrode disposed over the second gate insulating layer and connected to a source region of the first active pattern through a first contact hole penetrating the second gate insulating layer, the interlayer insulating layer, and the first gate insulating layer, and
a drain electrode disposed over the second gate insulating layer and connected to a drain region of the first active pattern through a second contact hole penetrating the second gate insulating layer, the interlayer insulating layer, and the first gate insulating layer,
wherein the second gate electrode comprises a same material as the source electrode and the drain electrode.

29. The stretchable display device of claim 13, further comprising:
a source electrode disposed over the second gate insulating layer and connected to a source region of the first active pattern through a first contact hole penetrating the second gate insulating layer, the interlayer insulating layer, and the first gate insulating layer, and
a drain electrode disposed over the second gate insulating layer and connected to a drain region of the first active pattern through a second contact hole penetrating the second gate insulating layer, the interlayer insulating layer, and the first gate insulating layer,
wherein a portion of the second gate electrode is disposed on a same layer as the source electrode and the drain electrode.

30. The stretchable display device of claim 13, further comprising a pad disposed in the pad area,
wherein the pad comprises:
a first pad layer disposed over the first gate insulating layer; and
a second pad layer disposed over the first pad layer exposed by a third open area penetrating the interlayer insulating layer.

31. The stretchable display device of claim 30, wherein the second electrode comprises a same material as the second pad layer.

32. The stretchable display device of claim 30, wherein the pad further comprises a third pad layer disposed over the second pad layer exposed by a fourth open area penetrating the second gate insulating layer, and
wherein the second gate electrode comprises a same material as the third pad layer.

33. A thin-film transistor array substrate comprising:
a buffer layer disposed over a substrate;
a first gate insulating layer disposed over the buffer layer,
an interlayer insulating layer disposed over the first gate insulating layer;
a first open area penetrating the interlayer insulating layer, the first gate insulating layer, and the buffer layer to expose a portion of the substrate;
a first thin-film transistor; and
a second thin-film transistor,
wherein the first thin-film transistor comprises:
a first oxide semiconductor pattern disposed over the buffer layer and covered with the first gate insulating layer,
the first gate insulating layer; and
a first gate electrode disposed over the first gate insulating layer to overlap a portion of the first oxide semiconductor pattern, and
wherein the second thin-film transistor comprises:
a first electrode disposed over the substrate, with at least a portion of the first electrode being exposed by the first open area;
a second electrode disposed over the interlayer insulating layer above the first electrode to be adjacent to the first open area;
a second oxide semiconductor pattern disposed over the second electrode, and extending to the first electrode along a side surface of the interlayer insulating layer, a side surface of the first gate insulating layer, and a side surface of the buffer layer exposed by the first open area;
a second gate insulating layer disposed over the interlayer insulating layer and covering the second oxide semiconductor pattern; and
a second gate electrode disposed over the second gate insulating layer to overlap the second oxide semiconductor pattern.
